(19) United States
(12) Patent Application Publication
(10) Pub. No.: US 2025/0372407 A1
(43) Pub. Date: Dec. 4, 2025

(54) ULTRASONIC BONDING FOR PROCESS CHAMBER COMPONENTS

(71) Applicant: Applied Materials, Inc., Santa Clara, CA (US)

(72) Inventors: Marc David Shull, Los Gatos, CA (US); Joseph Frederick Behnke, San Jose, CA (US); Chao Liu, San Jose, CA (US); Christopher Beaudry, San Jose, CA (US)

(21) Appl. No.: 18/731,050

(22) Filed: May 31, 2024

(51) Int. Cl. H01L 21/607; H01L 21/02; H01L 21/449

(52) U.S. Cl. CPC H01L 21/607; H01L 21/02175; H01L 21/449

(57) ABSTRACT

An article includes a body and an ultrasonic bonded layer deposited on the body. The ultrasonic bonded layer includes a first layer of a first material. The first material includes a metal or metal alloy, The ultrasonic bonded layer further includes a second layer of a second material bonded to the first layer. The second material includes a metal matrix composite material.

### TECHNICAL FIELD

Embodiments of the present disclosure relate, in general, to process chamber components and methods of manufacturing the same. Specifically, embodiments of the present disclosure related to ultrasonic bonded process chamber components, and methods of manufacturing the same.

### BACKGROUND

Various manufacturing processes, including semiconductor device manufacturing processes, expose chamber components and their coating materials to high temperatures, high energy plasma, a mixture of corrosive gases, high stress, high strength electric fields, and combinations thereof. These extreme conditions may increase the components' and the coating materials' susceptibility to defects. Coatings are used which are effective at protecting chamber components from one or more of these damaging conditions. In some cases, a compromise may be made between strength or other mechanical properties of a material, and resistance to process conditions of the process chamber exhibited by the material.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the disclosure, an article includes a body and an ultrasonic bonded layer deposited on the body. The ultrasonic bonded layer includes a first layer of a first material. The first material includes a metal or metal alloy, The ultrasonic bonded layer further includes a second layer of a second material bonded to the first layer. The second material includes a metal matrix composite material.

In another aspect of the disclosure, a method includes disposing a first foil of a first material on a body. The body may be or include at least part of a component of a substrate processing chamber. The method further includes providing ultrasonic vibrations to bond the first foil to the body. The method further includes disposing a second foil of a second material on the first foil. The method further includes providing ultrasonic vibrations to bond the second foil to the first foil.

In another aspect of the disclosure, a substrate processing chamber includes a faceplate. The faceplate includes a body and an ultrasonic bonded layer deposited on the body. The ultrasonic bonded layer includes a first layer of a first material. The first material includes a metal or metal alloy, The ultrasonic bonded layer further includes a second layer of a second material bonded to the first layer. The second material includes a metal matrix composite material.

### BRIEF DESCRIPTION OF THE DRAWINGS

The present disclosure is illustrated by way of example, and not by way of limitation. It should be noted that different references to “an” or “one” embodiment in this disclosure are not necessarily to the same embodiment, and such references mean at least one.

FIG. 1 is a sectional view of a processing chamber having one or more chamber components that may be manufactured with techniques including ultrasonic processing, according to some embodiments.

FIG. 2 depicts a sectional view of an example coated article, according to some embodiments.

FIG. 3 depicts a cross-sectional view of a faceplate manufactured utilizing ultrasonic processing techniques, according to some embodiments.

FIG. 4 is a schematic diagram of an example ultrasonic processing apparatus, according to some embodiments.

FIG. 5 is a flow diagram of a method for manufacturing a component using ultrasonic processing techniques, according to some embodiments.

### DETAILED DESCRIPTION

Described herein are technologies related to manufacture, modification, and use of components of a manufacturing chamber, such as a semiconductor device manufacturing chamber, by providing materials via ultrasonic processing. Manufacturing equipment (e.g., processing chambers) is used to process substrates, such as semiconductor wafers. The properties of substrates are determined by the conditions in which the substrates were processed. Components of the processing chamber impact conditions proximate to the substrate, and have an effect on performance (e.g., target substrate properties, consistency of production, production yield, etc.). In some cases, components of the processing chamber may experience harsh or damaging environments. In some cases, components of a processing chamber may be used under conditions that benefit from mechanical material properties of the components, such as strength, rigidity, hardness, thermal expansion, etc. In some cases, materials of a component of a process chamber may be chosen as a compromise between various target properties of the component.

In some systems, plasma may be used to process a substrate. Plasma processing may include generating a plasma from a halogen-containing gas, such as C₂F₆, SF₆, SiCl₄, HBr, NF₃, CF₄, CHF₃, CH₂F₃, F₂, NF₃, Cl₂, CCl₄, BCl₃, ClF₃, and SiF₄, among others, and other gases such as O₂ or N₂O. Plasma may interact with components of the processing chamber. Contact with plasma may cause damage, corrosion, or wear to components of the processing chamber. Some materials, such as pure aluminum, may be resistant to damage from environments conducive to substrate processing, such as plasma environments.

In some systems, high temperatures may be used for substrate processing operations. Some components of a manufacturing system may be affected by high temperatures. For example, components may bend, bow, or warp in high temperature conditions. Some materials may be utilized that resist deformation at high temperatures for such components, such as strong metals, reinforced materials, hybrid materials, etc.

In some systems, a process chamber component may be precisely machined to a geometry suited for target performance of the process chamber component. For example, a gas distribution system may include a faceplate that provides gas via a number of holes or channels to a substrate processing region. Material of the component (e.g., faceplate) may be selected such that the component is easily machinable, to facilitate shaping of the component to a target geometry for use in the process chamber.

In some systems, various contributing factors lead to compromising on a single material that somewhat achieves disparate design goals for a substrate process chamber component. In some cases, a base material and a protective coating material may be used, but this may be a temporary solution, coating material on a component may be expensive (e.g., such as coating by atomic layer deposition which may include many cycles of providing various precursors to a surface of the component), coating components may be inconsistent or lead to uneven coatings of complex geometries (such as by physical or chemical vapor deposition), or the like. Concessions may be made in one or more aspects of performance of the process chamber component.

Methods and devices of the current disclosure may address at least some deficiencies of a conventional approach. In some embodiments, a chamber component (such as a faceplate for gas distribution) may be exposed to a corrosive environment, may be operated at high temperatures, and may be machined to a target shape to achieve target performance. The chamber component may include a body. The body may be of a target geometry, may be machined to a target shape, may have been formed using any manufacturing methods available, or the like. Further portions of the chamber component may be formed on top of the underlying body via additive manufacturing techniques. An additive manufacturing technique that may enable a chamber component with properties conducive to use in a substrate processing environment is ultrasonic processing.

Ultrasonic processing includes providing a thin layer of a target material to a body, such as a metal foil or tape. The foil or tape may be clamped or otherwise secured to the underlying body. Vibrations may be induced in the body to cause the foil or tape to bond to the body, e.g., by creating friction between the foil and the body. Vibrations may be ultrasonic. Vibrations may have frequencies on the order of thousands of cycles per second, e.g., 20,000 Hz. Vibrations may be applied by an ultrasonic processing head. Vibrations may be applied by an ultrasonic processing head which also provides the foil or tape. Ultrasonic bonding may be performed with various metal materials, including aluminum, steel, nickel, etc.

In some embodiments, ultrasonic processed materials may generate a body bonded to the foil, which may be of a different material than the body. One or both of the materials may be machinable. In some embodiments, an ultrasonic bonded article may be machined, e.g., after one or more layers are bonded to a body via an ultrasonic processing procedure, machining may be performed to shape a substrate process chamber component.

In some embodiments, a metal matrix composite (MMC) material may be provided to a body for ultrasonic processing. A metal matrix composite material comprises a composite material, with fibers, particles, or another geometry of material dispersed in a metallic matrix, such as copper, aluminum, or steel. A MMC material may be stronger, more resistant to deformation at high temperature, more durable, or the like than the material of the metallic matrix. The material dispersed in an MMC material may be a ceramic material, such as alumina, silica, silicon carbide, silicon nitride, ceria, zirconia, or another ceramic material. A ceramic may be in the form of fibers (e.g., long fibers than generate anisotropic strength in the resulting MMC material), whiskers (e.g., short fibers that generate an MMC material exhibiting isotropic properties), mesh, particles, or the like. Ultrasonic bonded MMC materials may be machined. MMC materials may be bonded via ultrasonic processing to other ultrasonic processed foils, a body of a chamber component, or the like.

In some embodiments, different materials may be provided via ultrasonic processing to tune properties of an article. For example, bonding between consecutive layers of MMC materials may be inconsistent, e.g., due to random positioning of areas rich in composite material and areas of metallic material causing variation in adherence between adjacent layers. In some embodiments, alternating layers of metal and MMC material may be provided via ultrasonic processing to generate a layered structure exhibiting strong bonding as well as advantageous properties of MMC materials. For example, MMC materials may have higher strength than metal components, which may enable less deformation at high temperatures, or may enable thinner components to be used which exhibit the same acceptable level of deformation of components that do not include MMC materials.

In some embodiments, upper layers may be provided via ultrasonic processing of materials that provide resistance to an environment of substrate processing. For example, pure nickel or pure aluminum may be deposited via ultrasonic processing to provide a protective layer to the chamber component. In some embodiments, pure aluminum may be too soft for manufacture of a chamber component, and aluminum alloys may be damaged by substrate processing environments, such as plasma environments. In some embodiments, pure nickel may be inconvenient due to expense, weight, or the like, for a chamber component, but may be provided as an upper protective layer to enhance corrosion resistance of a chamber component.

In some embodiments, generation of a chamber component by ultrasonic processing may enable manufacture of components that may be inconvenient, expensive, or impossible using other methods. For example, additional components may be embedded in a chamber component built by additive ultrasonic manufacturing techniques. Components such as flow controllers, sensors, valves, heaters or other electrodes, or the like may be embedded into a component by providing the components during ultrasonic processing operations.

In some embodiments, many target types of material may be bonded by ultrasonic processing. In other additive manufacturing techniques, such as stereolithography or extrusion, concessions may be made to enable processing of the material, and target alloys, pure metals, ceramic materials, or the like may be unavailable for bonding.

Methods and systems of the present disclosure offer advantages over conventional methods. Utilizing ultrasonic processing enables additive manufacturing of chamber components. Additive manufacturing provides advantages including opportunity to embed various sensors or other components. Additive manufacturing provides capability to build up complex geometric structures, such as channels for gas distribution operations in a faceplate of process chamber. Additive manufacturing provides opportunity to use a variety of materials, to tune properties of the chamber component. Ultrasonic processing provides additional advantages over other additive manufacturing methods, such as availability of applicable materials including pure metals, target metal alloys, MMC materials, metals without detrimental impurities, or the like. Devices of the present disclosure may exhibit higher strength, less deformation under high temperatures, and/or higher resistance to substrate processing environments than devices manufacturing via conventional methods.

In one aspect of the disclosure, an article includes a body and an ultrasonic bonded layer deposited on the body. The ultrasonic bonded layer includes a first layer of a first material. The first material includes a metal or metal alloy, The ultrasonic bonded layer further includes a second layer of a second material bonded to the first layer. The second material includes a metal matrix composite material.

In another aspect of the disclosure, a method includes disposing a first foil of a first material on a body. The body may be or include at least part of a component of a substrate processing chamber. The method further includes providing ultrasonic vibrations to bond the first foil to the body. The method further includes disposing a second foil of a second material on the first foil. The method further includes providing ultrasonic vibrations to bond the second foil to the first foil.

In another aspect of the disclosure, a substrate processing chamber includes a faceplate. The faceplate includes a body and an ultrasonic bonded layer deposited on the body. The ultrasonic bonded layer includes a first layer of a first material. The first material includes a metal or metal alloy, The ultrasonic bonded layer further includes a second layer of a second material bonded to the first layer. The second material includes a metal matrix composite material.

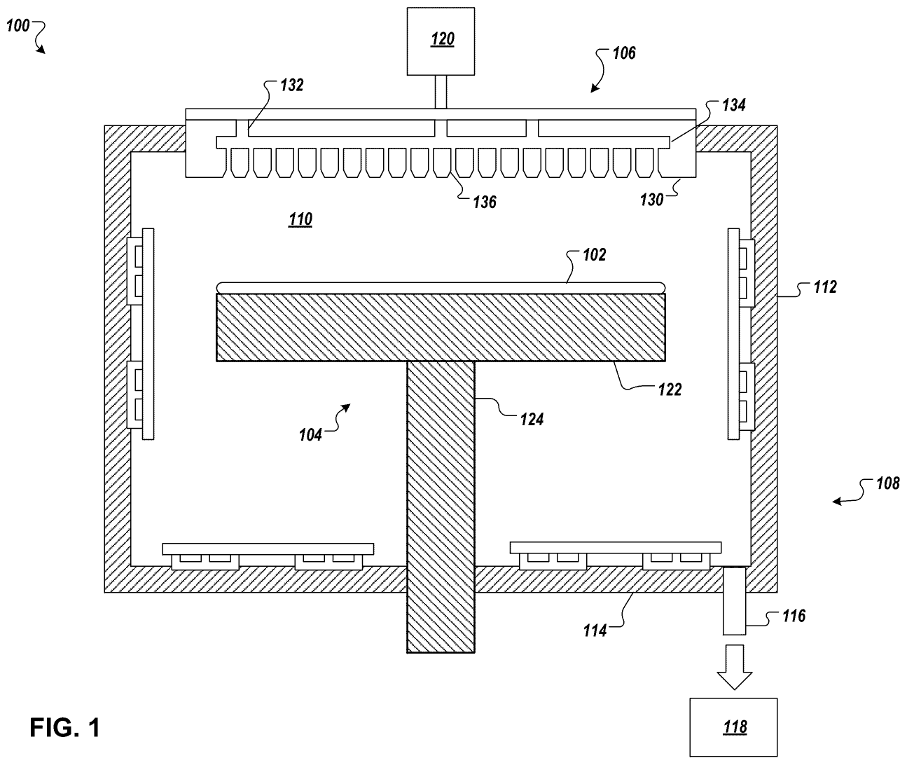

FIG. 1 is a sectional view of a process chamber 100 having one or more chamber components that may be manufactured with techniques including ultrasonic processing, according to some embodiments. Process chamber 100 may be used for processes in which a corrosive plasma environment having plasma processing conditions is provided. For example, the process chamber 100 may be a chamber for a plasma etcher or plasma etch reactor, a plasma cleaner, and so forth. Process chamber 100 may be a chamber used for deposition operations, e.g., for providing films, coatings, or the like on substrates. Examples of chamber components that may be manufactured with techniques including ultrasonic processing include a substrate support assembly 104, an electrostatic chuck (ESC), a ring (e.g., a process kit ring or single ring), a chamber wall, a base, a faceplate 130 (e.g., gas distribution plate), a showerhead 106, a nozzle, a lid, a liner, a liner kit, a shield, a plasma screen, a flow equalizer, a cooling base, a chamber viewport, a chamber lid, and so on.

In one embodiment, process chamber 100 includes a chamber body 108 and a showerhead 106 that enclose an interior volume 110. The showerhead may include a showerhead base and a showerhead gas distribution plate, e.g., faceplate 130. Alternatively, the showerhead 106 may be replaced by a lid and a nozzle in some embodiments. The chamber body 108 may be fabricated from aluminum, stainless steel or other suitable material. The chamber body 108 generally includes sidewalls 112 and a bottom 114. Faceplate 130 may be made of aluminum, nickel, ceramic, steel, and/or a combination of materials. Faceplate 130 may be manufactured utilizing techniques including ultrasonic processing.

Faceplate 130 may include one or more gas inlets 132. Gas inlets 132 may be associated with particular gas sources, gas delivery zones of process chamber 100 and/or faceplate 130, or the like. Faceplate 130 may further include a plenum 134, e.g., an interior space which may connect gas inlets 132 to gas outlets 136, which may enable mixing of various gases in faceplate 130, which may generate a target pressure profile of gases provided to various gas outlets 136 or gas outlet zones, or the like.

Faceplate 130 may be at least partially manufacturing utilizing ultrasonic processing techniques. In some embodiments, portions of faceplate 130 (e.g., a base portion, an underlying body, or the like) may be machined utilizing conventional machining methods (e.g., computer numerical control (CNC) machining, water jet machining, laser machining, stereolithography, etc.). Additional portions may be manufactured utilizing ultrasonic processing techniques.

In some embodiments, layers of material may be applied to a body comprising faceplate 130. The material added by ultrasonic processing may serve one or more functions. Ultrasonic processing may enable embedding of one or more devices in faceplate 130, such as sensors (e.g., fiber optics as part of a sensing system), flow controllers, valves, or the like. Ultrasonic processing may enable application of different materials to a machined body of a first material, such as different alloys of aluminum being used for the body and applied layers, metals of different properties to be applied in some layers, metal matrix composite (MMC) materials to be included in layers, etc. Faceplate 130 can be manufactured to take advantage of properties of various materials utilizing ultrasonic processing, e.g., an easily machinable base of aluminum alloy (e.g., 6061 aluminum alloy) may be combined with one or more layers of MMC material to provide additional structural strength (e.g., alumina fibers in aluminum foil). Further layers may be applied to protect faceplate 130 from process gases, plasma, or the like (e.g., pure nickel, pure aluminum, etc.). A component such as faceplate 130 may also be machined after ultrasonic processing operations, e.g., between ultrasonic processing steps when multiple layers of material are bonded to the body.

An exhaust port 116 may be defined in the chamber body 108, and may couple the interior volume 110 to a pump system 118. The pump system 118 may include one or more pumps and throttle valves utilized to evacuate and regulate the pressure of the interior volume 110 of processing chamber 100.

Showerhead 106 may be supported on the sidewall 112 of the chamber body 108. The showerhead 106 (or lid) may be opened to allow access to the interior volume 110 of processing chamber 100, and may provide a seal for processing chamber 100 while closed. A gas panel 120 may be coupled to processing chamber 100 to provide process and/or cleaning gases to the interior volume 110 through showerhead 106 or lid and nozzle. The showerhead 106 includes a gas distribution plate (GDP) having multiple gas delivery holes throughout the GDP.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃—ZrO₂. The nozzle may also be a ceramic, such as Y₂O₃, YAG, or the ceramic compound comprising Y₄Al₂O₉ and a solid-solution of Y₂O₃—ZrO₂. The lid, showerhead base, GDP and/or nozzle may be of metal and/or MMC materials, and may be manufactured with techniques including ultrasonic processing, in some embodiments.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases). The substrate support assembly 104 is disposed in the interior volume 110 of the processing chamber 100 below the showerhead 106 or lid. The substrate support assembly 104 holds the substrate 102 during processing. A ring (e.g., a single ring) may cover a portion of the support assembly 104 (e.g., susceptor 122), and may protect the covered portion from exposure to plasma during processing. The ring may be silicon or quartz in one embodiment. Substrate support assembly 104 may include a pedestal 124, and a susceptor 122.

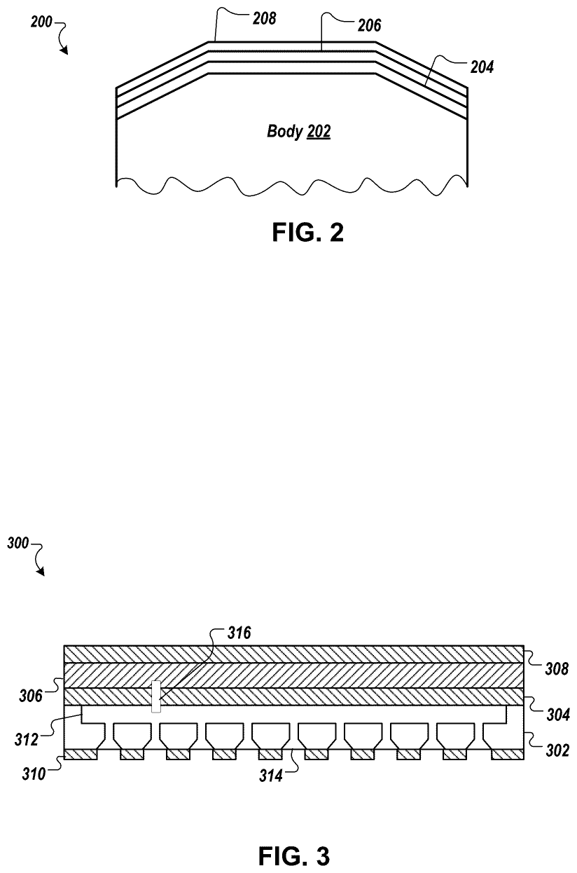

FIG. 2 depicts a sectional view of an example coated article, according to some embodiments. FIG. 2 illustrates a coated article 200 having a body 202 and layers of coatings 204, 206, and 208. Body 202 may be a body of any of various chamber components including but not limited to substrate support assembly, an electrostatic chuck (ESC), a ring (e.g., a process kit ring or single ring), a chamber wall, a base, a gas distribution plate, a faceplate, a showerhead, a nozzle, a lid, a liner, a liner kit, a shield, a plasma screen, a flow equalizer, a cooling base, a chamber viewport, a chamber lid, and so on. The body may be made from a metal (such as aluminum, stainless steel, nickel, etc.), a ceramic, a metal-ceramic composite, a polymer, a polymer ceramic composite, or other suitable materials.

In some embodiments, a layer 204 applied directly to body 202 may be applied utilizing ultrasonic processing techniques. In some embodiments, one or more primer layers are applied to body 202 before layer 204. In some embodiments, layer 204 may be applied to body 202, which may be machined using conventional methods. In some embodiments, layer 204 may be of the same or a similar material as body 202, such as the two materials sharing at least one component (e.g., an alloy). In some embodiments, providing a layer 204 by ultrasonic processing may enable generation of more complex geometries than conventional machining methods, such as plenum structures of a process chamber component. Layer 204 may be generated by bonding a series of foils via ultrasonic processing. Layer 204 may be generating by bonding a series of foils of one or more materials. Layer 204 may be generated from metal foils, such as aluminum, copper, steel, nickel, or the like. Layer 204 may include a number of foils bonded to body 202 and/or to each other. Foils may be about 200 micrometers thick. Foils may be between 100 and 500 μm thick. Foils may be between 10 and 700 μm thick. Foils may be between 5 and 1000 μm thick, or any sub-range of thicknesses as selected for a design of article 200. Layer 204 may be machinable, e.g., conventional machining methods may be utilized for shaping article 200 after one or more layers (layer 204, layer 206, layer 208, sub-layers of any of these layers, etc.) have been applied via ultrasonic processing methods. In some embodiments, layer 204 may be about 2000 μm thick. In some embodiments, layer 204 may be about 0.1 inches thick. In some embodiments, layer 204 may be between 1000 μm and 3000 μm thick. In some embodiments, layer 204 may be between 500 μm and 5000 μm thick. Layer 204 may be of different thicknesses, e.g., to accommodate a larger design of article 200. Layer 204 may be of any sub-range of thicknesses of those described here.

In some embodiments, another layer 206 may be provided to body 202, e.g., by ultrasonic processing. Layer 206 may include a different set of materials than layer 204, a different mixture of material components than layer 204, serve a different purpose than layer 206, contribute in a different way to operations of article 200 than layer 204, or the like. In some embodiments, layer 204 may be a metal or metal-containing material. In some embodiments, layer 206 may be or include a metal or metal-containing material. In some embodiments, layer 206 may include one or more MMC materials. MMC materials may include a similar material as the metal matrix as body 202, layer 204, or the like. In some embodiments, MMC foil layers may bond effectively to metal foil layers. In some embodiments, layer 206 may include alternating layers of MMC material and metal material (e.g., metal alloy). Layer 206 may share one or more thickness properties of layer 204, e.g., layer thickness ranges, foil thickness ranges, etc.

Layer 206 may include ceramic materials (e.g., plasma resistant ceramic materials as the material embedded in the metal matrix of an MMC material), such as ceramic oxides (e.g., alumina Al₂O₃, yttria Y₂O₃, yttrium aluminum garnet Y₃Al₅O₁₂, yttrium aluminum perovskite YAlO₃, zirconia ZrO₂, silicon dioxide SiO₂, Er₂O₃, ErAlₓO_{y}, YAlₓO_{y}, YZrₓO_{y} and YZrₓAl_{y}O_{z}, Gd₂O₃, Yb₂O₃, Y₂O₃ stabilized ZrO₂ (YSZ), Er₃Al₅O₁₂ (EAG), a Y₂O₃—ZrO₂ solid solution, or a composite ceramic comprising Y₄Al₂O₉ and a solid solution of Y₂O₃—ZrO₂, etc.), ceramic carbides (e.g., silicon carbide SiC, silicon-silicon carbide Si—SiC, boron carbide B₄C, etc.), nitride based ceramics (e.g., aluminum nitride AlN, silicon nitride SiN, etc.), other ceramic materials, or combinations of materials. Some additional examples of ceramic oxides that may be used for the layer 208 include yttrium-based oxides, erbium-based oxides, and so on. Additionally, ceramic fluorides and/or oxyfluorides may be used for the layer 208. Examples include YOₓF_{y}. YF₃, and so on.

In some embodiments, layer 206 is an MMC coating including metal oxide material, that includes or consists of yttria and zirconia (Y₂O₃—ZrO₂). The Y₂O₃—ZrO₂ may include 20-80 mol % Y₂O₃ and 20-80 mol % ZrO₂ in one embodiment. In a further embodiment, the Y₂O₃—ZrO₂ includes 30-70 mol % Y₂O₃ and 30-70 mol % ZrO₂. In a further embodiment, the Y₂O₃—ZrO₂ includes 40-60 mol % Y₂O₃ and 40-60 mol % ZrO₂. In a further embodiment, the Y₂O₃—ZrO₂ includes 50-80 mol % Y₂O₃ and 20-50 mol % ZrO₂. In a further embodiment, the Y₂O₃—ZrO₂ includes 60-70 mol % Y₂O₃ and 30-40 mol % ZrO₂. In other examples, the Y₂O₃—ZrO₂ may include 45-85 mol % Y₂O₃ and 15-60 mol % ZrO₂, 55-75 mol % Y₂O₃ and 25-45 mol % ZrO₂, 58-62 mol % Y₂O₃ and 38-42 mol % ZrO₂, and 68-72 mol % Y₂O₃ and 28-32 mol % ZrO₂.

In various embodiments, layer 206 may be composed of Y₃Al₅O₁₂ (YAG), Y₄Al₂O₉ (YAM), Er₃Al₅O₁₂ (EAG), Gd₃Al₅O₁₂ (GAG), YAlO₃ (YAP), Er₄Al₂O₉ (EAM), ErAlO₃ (EAP), Gd₄Al₂O₉ (GdAM), GdAlO₃ (GdAP), Nd₃Al₅O₁₂ (NdAG), Nd₄Al₂O₉ (NdAM), NdAlO₃ (NdAP), and/or a ceramic compound comprising Y₄Al₂O₉ and a solid-solution of Y₂O₃—ZrO₂. The layer 208 may also be Er—Y compositions (e.g., Er 80 wt % and Y 20 wt %), Er—Al—Y compositions (e.g., Er 70 wt %, Al 10 wt %, and Y 20 wt %), Er—Y—Zr compositions (e.g., Er 70 wt %, Y 20 wt % and Zr 10 wt %), or Er—Al compositions (e.g., Er 80 wt % and Al 20 wt %). Note that wt % means percentage by weight. In contrast, mol % is molar ratio.

The layer 206 may also include ceramic material based on a solid solution formed by any of the aforementioned ceramics. With reference to the ceramic compound comprising Y₄Al₂O₉ and a solid-solution of Y₂O₃—ZrO₂, in one embodiment, the ceramic compound includes 62.93 molar ratio (mol %) Y₂O₃, 23.23 mol % ZrO₂ and 13.94 mol % Al₂O₃. In another embodiment, the ceramic compound can include Y₂O₃ in a range of 50-75 mol %, ZrO₂ in a range of 10-30 mol % and Al₂O₃ in a range of 10-30 mol %. In another embodiment, the ceramic compound can include Y₂O₃ in a range of 40-100 mol %, ZrO₂ in a range of 0-60 mol % and Al₂O₃ in a range of 0-10 mol %. In another embodiment, the ceramic compound can include Y₂O₃ in a range of 40-60 mol %, ZrO₂ in a range of 30-50 mol % and Al₂O₃ in a range of 10-20 mol %. In another embodiment, the ceramic compound can include Y₂O₃ in a range of 40-50 mol %, ZrO₂ in a range of 20-40 mol % and Al₂O₃ in a range of 20-40 mol %. In another embodiment, the ceramic compound can include Y₂O₃ in a range of 70-90 mol %, ZrO₂ in a range of 0-20 mol % and Al₂O₃ in a range of 10-20 mol %. In another embodiment, the ceramic compound can include Y₂O₃ in a range of 60-80 mol %, ZrO₂ in a range of 0-10 mol % and Al₂O₃ in a range of 20-40 mol %. In another embodiment, the ceramic compound can include Y₂O₃ in a range of 40-60 mol %, ZrO₂ in a range of 0-20 mol % and Al₂O₃ in a range of 30-40 mol %. In other embodiments, other distributions may also be used for the ceramic compound.

Any of the aforementioned ceramic material of a MMC material of layer 206 may contain one or more dopants that combined comprise up to about 2 mol % of the coating. Such dopants may be rare earth oxides from the lanthanide series, such as Er (erbium), Ce (cerium), Gd (gadolinium), Yb (ytterbium), Lu (lutetium), and so on. Such dopants may additionally or alternatively include Al (aluminum) and/or Si (silicon).

Layer 208 may be disposed on layer 206, e.g., by ultrasonic processing techniques. Layer 208 may be of a material selected to be resistant to an environment of a process chamber, such as a reactive environment, corrosive environment, plasma environment, or the like. Layer 208 may be a metal material. Layer 208 may be aluminum, nickel, steel, or another material. Layer 208 may be of pure aluminum (e.g., aluminum 1100), pure nickel, or the like. Layer 208 may share one or more features with layer 204, e.g., in terms of a thickness of layer 208, a thickness of foil used in generating layer 208, or the like.

FIG. 3 depicts a cross-sectional view of faceplate 300 manufactured utilizing ultrasonic processing techniques, according to some embodiments. Faceplate 300 includes body 302, and ultrasonic layers 304, 306, 308, and 310. Faceplate 300 may be essentially cylindrical, with FIG. 3 depicting an essentially rectangular cross-section of the cylindrical faceplate 300.

Ultrasonic layers 304, 306, and 308 may be similar and/or share one or more features with layers 204, 206, and 208 of FIG. 2. In some embodiments, layer 304 may include a number of foils, bonded utilizing ultrasonic bonding techniques. Layer 304 may include metal material, material selected to optimize a bond with body 302, material resistant to process gases that may be found in plenum 312, or the like. Layer 306 may include a material for reinforcing strength of faceplate 300, such as MMC material. Layer 306 may include alternating layers of metal and MMC materials. Layer 308 may include material for reinforcement of faceplate 300, material for protecting faceplate 300 from a process gas, or the like. In some embodiments, one or more layers depicted in FIG. 3 may not be included. For example, a process chamber component designed for use without contact with process gas may include reinforcing materials, such as those of layer 306, without including resistant materials (e.g., layers 304 and 308).

Faceplate 300 includes layer 310. Layer 310 may be bonded to body 302 by ultrasonic processing techniques. Layer 310 may be of a material selected to protect faceplate 300 from a process environment, process gases, plasma, or the like. Layer 310 may be of pure aluminum. Layer 310 may be of pure nickel. Layer 310 may be of another material bonded to body 302 via ultrasonic processing techniques.

Plenum 312 may enable gas to be provided to one or more outlets 314 of faceplate 300. Plenum 312 may connect one or more gas inlets of faceplate 300 to outlets 314. Plenum 312 may include structures defining channels, chambers, flow paths, mixing volumes, and the like for operations of faceplate 300. Plenum 312 may be designed to provide gas inputs from one or more inlets to various gas outlet zones. For example, faceplate 300 may include a central gas outlet zone, an outer gas outlet zone, and an intermediate gas outlet zone. Plenum 312 may be designed to enable target gas mixing, pressure, timing, etc., for delivery of process, cleaning, or other gases to a process chamber via faceplate 300.

Faceplate 300 may include one or more embedded structures 316. Embedded structures may be disposed within faceplate 300, e.g., by adding the structures during additive manufacturing, ultrasonic processing, etc. Embedded structure 316 may be a flow controller (e.g., needle valve), sensor (e.g., fiber optic sensor), valve, or the like. Embedded structure 316 may include portions extending beyond faceplate 300, e.g., connections for providing instructions to a flow controller, one or more connections for receiving data from a sensor, or the like. In some embodiments, embedded structure 316 may determine, affect, and/or monitor conditions of a gas of faceplate 300, conditions of plenum 312, or the like.

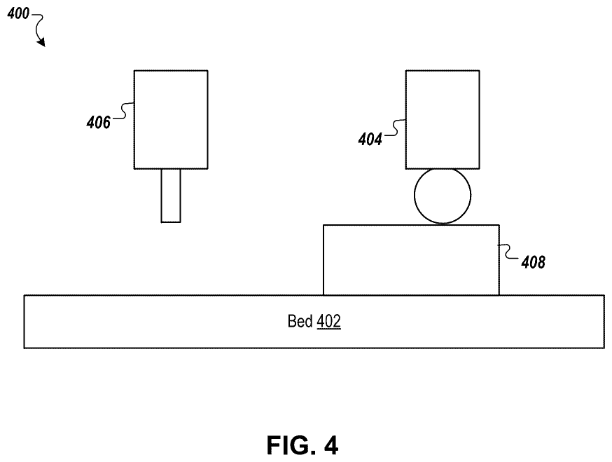

FIG. 4 is a schematic diagram of an example ultrasonic processing apparatus 400, according to some embodiments. Ultrasonic processing apparatus 400 includes bed 402, weld head 404, and spindle 406. In some embodiments, a body 408 may be clamped or otherwise secured to bed 402. Weld head 404 may be used to provide tape or foil of a target material for ultrasonic processing bonding to body 408.

Weld head 404 may further provide vibrational energy to body 408 and the tape or foil to be bonded to body 408. Weld head 404 may transmit ultrasonic vibrations (e.g., 20,000 Hz vibrations) generated by a device such as a piezo-electric transducer to body 408. Successive applications of foils to body 408 may enable building up a target article via ultrasonic processing manufacturing techniques. Application of ultrasonic vibrations to body 408 may generate a solid-state weld, may comprise a solid-state deposition process, etc. Bed 402 may be configured to move, such that a target portion of body 408 is disposed at weld head 404. Weld head 404 may include a portion configured to roll over body 408, e.g., a cylindrical portion, which may apply foil or tape and provide ultrasonic vibrations for bonding of body 408 to the foil. In some embodiments, body 408 may comprise a component of a substrate processing chamber, such as a face plate. In some embodiments, foil material provided to body 408 for ultrasonic processing may include metal, metal alloy, MMC material, pure nickel, pure aluminum, ceramic material suspended in a metallic matrix, etc. In some embodiments, weld head 404 may continuously roll over body 408 as bed 402 moves, which may generate a continuous ultrasonic weld along a length of deposited tape.

Ultrasonic processing apparatus 400 further includes spindle 406. Spindle 406 may be a conventional machining spindle, e.g., may include or be coupled to a milling tool, machining tool, or other tool for performing machining operations on body 408. In some embodiments, after bonding a foil to body 408, conventional machining operations may be performed by spindle 406 of ultrasonic processing apparatus 400 to further and/or precisely shape body 408 to a target geometry, such as forming structures of a component of a substrate processing chamber.

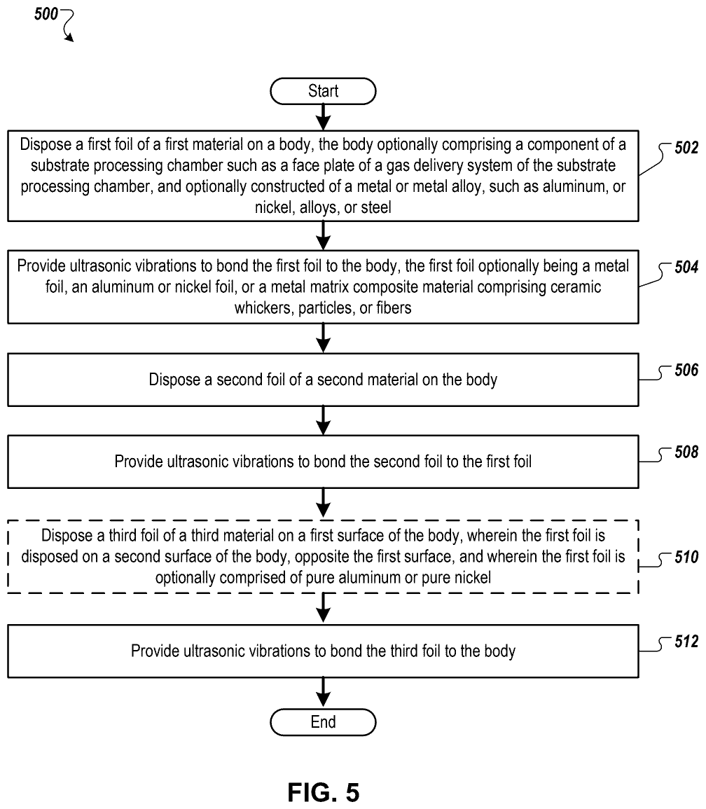

FIG. 5 is a flow diagram of a method 500 for manufacturing a component using ultrasonic processing techniques, according to some embodiments. At block 502, a first foil of a first material is disposed on a body. The body may be or comprise at least a portion of a component of a substrate processing chamber, such as a face plate of a gas delivery system of the substrate processing chamber. The body may be made of a metal or metal alloy, such as aluminum, steel, nickel, or the like.

At block 504, ultrasonic vibrations are provided to bond the first foil to the body. The ultrasonic vibrations may be provided via a weld head to bond the body to the first foil. The first foil may be a metal foil, such as an aluminum or nickel foil. The first foil may be of an MMC material, and may include ceramic components. The ceramic components may be fibers (e.g., long fibers resulting in an anisotropic MMC material), whiskers, particles, or another form of ceramic component suspended in a metallic matrix. The foil may be between about half of a thousandth of an inch, and about thirty thousandths of an inch thick.

At block 506, a second foil of a second material is disposed on the body, e.g., on the first foil. Additional operations of foil deposition may be performed, e.g., to cover a surface of the body before proceeding to additional layers. The second foil may be of one of the materials listed in connection with the first foil. The second foil may be approximately the same thickness as the first foil. The second foil may be within a thickness range discussed in connection with the first foil.

At block 508, ultrasonic vibrations are provided to bond the second foil to the first foil. The ultrasonic vibrations may be approximately 20,000 Hz.

At block 510, a third foil of a third material is optionally disposed on a surface of the body. The third foil may be of a different material than one or both of the first and second foils. The third foil may be placed on a different surface than the surface built up by the second and third foils. For example, the first and second foils may be applied to a back side (e.g., opposite from the process side) of a face plate, and the third foil may be applied to the front side (e.g., process side) of the face plate. The first foil may have been deposited on a surface opposite the surface associated with the third foil. The third foil may optionally include or be composed of essentially pure nickel or aluminum. At block 512, ultrasonic vibrations may be provided to bond the third foil to the body.

The preceding description sets forth numerous specific details such as examples of specific systems, components, methods, and so forth, in order to provide a good understanding of several embodiments of the present disclosure. It will be apparent to one skilled in the art that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Preceding descriptions refer to applying coatings to various components, bodies, articles, etc. In some cases, a coating or layer is described as being applied “on” or “onto” a body, layer, material, etc. Unless clear from the context, a layer described as being “on” a layer, body, component, material, etc., may not be directly adjacent to what the layer is on, and there may be an intervening layer of another material between.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. An article, comprising:
a body; and
an ultrasonic bonded layer deposited on the body, the ultrasonic bonded layer comprising:
a first layer of a first material, the first material comprising a metal or metal alloy; and
a second layer of a second material bonded to the first layer, the second material comprising a metal matrix composite material.

2. The article of claim 1, wherein the article comprises a faceplate of a gas delivery system of a process chamber.

3. The article of claim 1, wherein the first material comprises aluminum, nickel, copper, or steel.

4. The article of claim 1, wherein the second material comprises a ceramic material impregnated in a metallic matrix.

5. The article of claim 4, wherein the ceramic material comprises alumina, silica, silicon carbide, or silicon nitride.

6. The article of claim 4, wherein the ceramic material is in the form of whiskers, fibers, particles, or mesh.

7. The article of claim 4, wherein the first layer has a thickness between 5 micrometers and 1000 micrometers.

8. The article of claim 4, further comprising a flow controller or sensor embedded in the ultrasonic bonded layer.

9. The article of claim 1, further comprising a protective metal layer deposited on a first side of the body, wherein the ultrasonic bonded layer is disposed on a second side of the body, opposite the first side of the body, and wherein the protective metal layer comprises nickel or aluminum.

10. A method, comprising:
disposing a first foil of a first material on a body, the body comprising a component of a substrate processing chamber;
providing ultrasonic vibrations to bond the first foil to the body;
disposing a second foil of a second material on the first foil; and
providing ultrasonic vibrations to bond the second foil to the first foil.

11. The method of claim 10, wherein the first foil comprises a metal foil.

12. The method of claim 10, wherein the second material comprises a metal matrix composite material.

13. The method of claim 12, wherein the metal matrix composite material comprises a ceramic material in the form of fibers, whiskers, of particles impregnated in a metal matrix material.

14. The method of claim 10, further comprising:
disposing a third foil of a third material on a first surface of the body, wherein the first foil is deposited on a second surface of the body, opposite the first surface; and
providing ultrasonic vibrations to bond the third foil to the body.

15. The method of claim 14, wherein the body comprises aluminum, and wherein the third material comprises nickel.

16. The method of claim 10, wherein the body comprise a face plate of a gas delivery system of the substrate processing chamber.

17. A substrate processing chamber comprising a faceplate, the faceplate comprising:
a body; and
an ultrasonic bonded layer deposited on the body, the ultrasonic bonded layer comprising:
a first layer of a first material, the first material comprising a metal or metal alloy; and
a second layer of a second material bonded to the first layer, the second material comprising a metal matrix composite material.

18. The substrate processing chamber of claim 17, wherein the metal matrix composite material comprises a ceramic material in the form of fibers, whiskers, of particles impregnated in a metal matrix material.

19. The substrate processing chamber of claim 18, wherein the metal matrix composite material comprises alumina, silicon carbide, or silicon nitride impregnated in an aluminum matrix.

20. The substrate processing chamber of claim 17, wherein the first layer has a thickness between 5 micrometers and 1000 micrometers.
